(19) United States
(12) Patent Application Publication
(10) Pub. No.: US 2026/0371817 A1
(43) Pub. Date: Nov. 19, 2026

(54) MICRO LIGHT EMITTING DEVICE APPARATUS

(71) Applicant: PlayNitride Display Co., Ltd., MiaoLi County (TW)

(72) Inventors: Cheng-Yuan Wu, MiaoLi County (TW); Yu-Yun Lo, MiaoLi County (TW); Chih-Ling Wu, MiaoLi County (TW); Tsai-Yi Chen, MiaoLi County (TW); Po-Wei Chiu, MiaoLi County (TW); LOGANATHAN MURUGAN, MiaoLi County (TW); Ying-Shin Huang, MiaoLi County (TW); Yu-Kai Huang, MiaoLi County (TW)

(73) Assignee: PlayNitride Display Co., Ltd., MiaoLi County (TW)

(21) Appl. No.: 19/678,084

(22) Filed: May 14, 2026

Related U.S. Application Data
(63) Continuation-in-part of application No. 19/243,732, filed on Jun. 20, 2025.

(30) Foreign Application Priority Data
May 15, 2025 (TW) 114118209

(51) Int. Cl. H10H 29/80; H10H 29/14; H10H 29/85; H10H 29/851; H10H 29/856

(52) U.S. Cl. CPC H10H 29/842; H10H 29/142; H10H 29/8512; H10H 29/8517; H10H 29/856

(57) ABSTRACT

A micro light emitting device apparatus including a circuit substrate, a pixel structure layer, a plurality of first reflective structures, a plurality of optical structures, a plurality of first color conversion layers and a protective layer is provided. The pixel structure layer, disposed on the circuit substrate, includes multiple micro light emitting elements. The first reflective structures, disposed on a side of the pixel structure layer away from the circuit substrate, define multiple accommodating spaces with the pixel structure layer. Each of the accommodating spaces exposes a light emitting surface of each micro light emitting element. The accommodating spaces include multiple first accommodating spaces and second accommodating spaces. The optical structures are disposed in the first accommodating spaces. The first color conversion layers are disposed in a part of the second accommodating spaces. The protective layer, disposed on the first color conversion layers, directly contacts the first color conversion layers.

### CROSS-REFERENCE TO RELATED APPLICATION

This application is a continuation-in-part application of and claims the priority benefit of U.S. application serial no. 19/243,732, filed on Jun. 20, 2025, which claims the priority benefit of Taiwan application serial no. 114118209, filed on May 15, 2025. The entirety of each of the above-mentioned patent applications is hereby incorporated by reference herein and made a part of this specification.

### BACKGROUND

### Technical Field

The disclosure relates to a light emitting apparatus, and particularly relates to a micro light emitting device apparatus.

### Description of Related Art

In the manufacturing process of current micro light emitting device apparatus, inkjet processes, vapor deposition processes, or printing processes are commonly used to form different functional layers. When the structure of the device is uneven or has special structural designs, it may easily cause some materials to remain in subsequent processes, thereby affecting the effectiveness or yield of the entire device apparatus. To solve the problem of material residue, conventional technology first sets up a patterned sacrificial layer to define the filling area for subsequent materials, fills the material at the target position after a large-area film deposition process, and then removes the patterned sacrificial layer. Thereby, the formed patterned functional layer will only have filling material at the target position. However, in addition to resulting in low material utilization, the above approach requires repeatedly covering and removing the patterned sacrificial layer when different materials are to be used to set up functional layers, significantly increasing material waste.

Furthermore, in current micro light emitting device apparatus, different color conversion materials or light-filtering materials are used to convert a portion of blue light micro light emitting elements into red light or green light, to accelerate the manufacturing process and improve the uniformity of monochromatic light. Thus, after forming a filter layer on the color conversion layer, the surface height of the filter layer will significantly exceed that of the blue sub pixel area where wavelength is not converted. However, the above structure may easily cause light-filtering material to remain in the blue sub pixel area due to the height difference, resulting in blue light being blocked and affecting the brightness and color purity of the entire pixel. In addition, the uneven structure formed above may also cause uneven film thickness in subsequent film deposition processes, thereby affecting the optical and electrical performance of the micro light emitting device apparatus.

On the other hand, conventional color conversion layers are mostly implemented using quantum dot elements, and the quantum dot elements are typically formed of a photoresist material. However, during complex processes such as photolithography, the quantum dots are susceptible to interaction with materials used in the process, which may result in structural damage or reduced light-emitting efficiency. Accordingly, there is a need for a more robust structural design.

### SUMMARY

The disclosure provides a micro light emitting device apparatus, which has better optical performance and reliability.

The micro light emitting device apparatus of the disclosure includes a circuit substrate, a pixel structure layer, a plurality of first reflective structures, a plurality of optical structures, a plurality of first color conversion layers and a protective layer. The pixel structure layer is disposed on the circuit substrate and includes a plurality of micro light emitting elements. The first reflective structures are disposed on a side of the pixel structure layer away from the circuit substrate and define a plurality of accommodating spaces with the pixel structure layer. Each of the accommodating spaces exposes a light emitting surface of each of the micro light emitting elements. The accommodating spaces include a plurality of first accommodating spaces and a plurality of second accommodating spaces. The optical structures are respectively disposed in the first accommodating spaces. The first color conversion layers are disposed in a part of the second accommodating spaces. The protective layer is disposed on the first color conversion layers and directly contacts a surface of the first color conversion layers.

Based on the above, in the design of the micro light emitting device apparatus of the disclosure, a protective layer is disposed on the optical structure and the color conversion layer, and the protective layer is in direct contact with a surface of the color conversion layer. Accordingly, defects or degradation of the color conversion layer caused by contact with process materials in subsequent processes can be avoided, thereby preventing structural damage or reduced light-emitting efficiency. The provision of the protective layer not only improves the manufacturing yield of the micro light emitting device apparatus, but also significantly enhances its tolerance in high-temperature testing environments.

In order to make the above-mentioned features and advantages of the disclosure comprehensible, embodiments accompanied with drawings are described in detail below.

### BRIEF DESCRIPTION OF THE DRAWINGS

FIG. 1 is a cross-sectional schematic diagram of a micro light emitting device apparatus according to an embodiment of the disclosure.

FIG. 2 is a cross-sectional schematic diagram of a micro light emitting device apparatus according to another embodiment of the disclosure.

FIG. 3 is a cross-sectional schematic diagram of a micro light emitting device apparatus according to another embodiment of the disclosure.

FIG. 4 is a cross-sectional schematic diagram of a micro light emitting device apparatus according to another embodiment of the disclosure.

FIG. 5 is a cross-sectional schematic diagram of a micro light emitting device apparatus according to another embodiment of the disclosure.

FIG. 6 is a cross-sectional schematic diagram of a micro light emitting device apparatus according to another embodiment of the disclosure.

FIG. 7 is a cross-sectional schematic diagram of a micro light emitting device apparatus according to another embodiment of the disclosure.

FIG. 8 is a cross-sectional schematic diagram of a micro light emitting device apparatus according to another embodiment of the disclosure.

FIGS. 9A-9H are cross-sectional schematic diagrams illustrating a manufacturing process of the micro light emitting device apparatus of FIG. 8.

FIG. 10 is a cross-sectional schematic diagram of a micro light emitting device apparatus according to another embodiment of the disclosure.

FIG. 11 is a graph illustrating normalized brightness of blue light and green light emitted from the micro light emitting device apparatus of FIG. 8 as a function of time.

FIG. 12 is a graph illustrating normalized brightness of blue light and green light emitted from a micro light emitting device apparatus of a comparative example as a function of time.

FIG. 13 is a cross-sectional schematic diagram of a micro light emitting device apparatus according to another embodiment of the disclosure.

FIG. 14 is a cross-sectional schematic diagram of a micro light emitting device apparatus according to another embodiment of the disclosure.

### DESCRIPTION OF THE EMBODIMENTS

The embodiments of the disclosure can be understood together with the drawings, and the drawings of the disclosure are also regarded as a part of the disclosure. It should be understood that the drawings of the disclosure are not drawn to scale and, in fact, the dimensions of elements may be arbitrarily expanded or reduced in order to clearly represent the features of the disclosure.

Unless expressly stated otherwise, directional terms (e.g., up, down, left, right, top portion, bottom portion) as used herein are used for reference only to the drawings and are not intended to imply absolute orientation. In addition, unless expressly stated otherwise, any method described herein is in no way intended to be construed as requiring execution of its steps in a particular order.

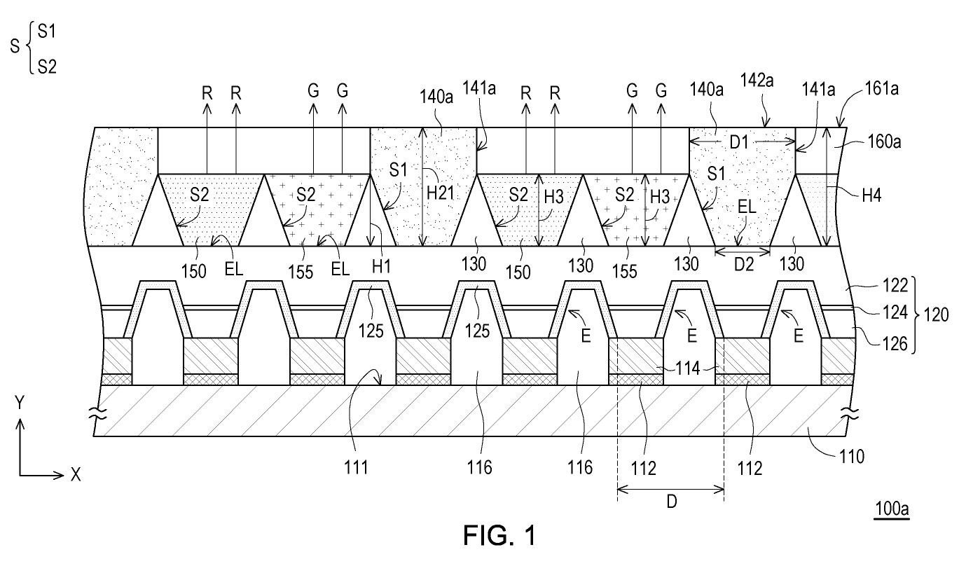

FIG. 1 is a cross-sectional schematic diagram of a micro light emitting device apparatus according to an embodiment of the disclosure. Referring to FIG. 1, in this embodiment, the micro light emitting device apparatus 100a includes a circuit substrate 110, a pixel structure layer 120, a plurality of first reflective structures 130, and a plurality of optical structures 140a. The pixel structure layer 120 is configured on the circuit substrate 110 and includes a plurality of micro light emitting elements E. From a cross-sectional view, these first reflective structures 130 are separately configured on a side of the pixel structure layer 120 away from the circuit substrate 110 and define a plurality of accommodating spaces S with the pixel structure layer 120. Each accommodating space S exposes a light emitting surface EL of each micro light emitting device E. These accommodating spaces S include a plurality of first accommodating spaces S1 and a plurality of second accommodating spaces S2. These optical structures 140a are respectively configured in these first accommodating spaces S1. Each first reflective structure 130 has a first height H1 relative to the light emitting surface EL, while each optical structure 140a has a second height H21 relative to the light emitting surface EL, and the second height H21 is greater than the first height H1, i.e., H21>H1.

In detail, the circuit substrate 110 of this embodiment is a driving substrate for driving the micro light emitting elements E to emit light. The circuit substrate 110 may include a plurality of pads 112 and a plurality of electrodes 114 set on these pads 112. The electrodes 114 are respectively set corresponding to the micro light emitting elements E of the pixel structure layer 120, and each electrode 114 may be electrically connected to the corresponding pad 112. The circuit substrate 110 may further include a solder mask 116, where the solder mask 116 is set between a bonding surface 111 and the pixel structure layer 120 to prevent short circuits between the electrodes 114.

Moreover, the pixel structure layer 120 of this embodiment is set on the bonding surface 111 of the circuit substrate 110. In one embodiment, a plurality of pixels (not shown) are arranged in a matrix to define the pixel structure layer 120, in which each full-color pixel includes three independently primary color (R, G, B) sub pixels, and may form various colored lights by adjusting the proportion of the three primary color beams provided by each sub pixel according to the target color, and each sub pixel includes one micro light emitting device E. Each micro light emitting device E includes a first type semiconductor layer 122, a light emitting layer 124, and a second type semiconductor layer 126 stacked in sequence. The light emitting layer 124 is sandwiched between the first type semiconductor layer 122 and the second type semiconductor layer 126. For example, the first type semiconductor layer 122 may be an N-type semiconductor, the second type semiconductor layer 126 may be a P-type semiconductor, and the light emitting layer 124 may be a multiple quantum well (MQW) layer, but the disclosure is not limited thereto.

In addition, the first type semiconductor layer 122 of the pixel structure layer 120 may be in a continuous state, and these micro light emitting elements E may share this first type semiconductor layer 122, but the disclosure is not limited thereto. For example, the first type semiconductor layer 122 may be a P-type semiconductor (in this case, a common P-type structure may be formed), and the second type semiconductor layer 126 may be an N-type semiconductor. In this embodiment, the circuit substrate 110 may further include a common electrode (not shown), which is electrically connected to the first type semiconductor layer 122 of the micro light emitting elements E via a conductive component (not shown). In addition, in these micro light emitting elements E, except for the areas in contact with the electrodes 114, the other surfaces of the micro light emitting elements E facing the circuit substrate 110 are set with an insulation layer 125, which is used to protect the structure of the micro light emitting elements E.

Referring to FIG. 1 again, the first reflective structures 130 are separately in contact with the side of the pixel structure layer 120 away from the circuit substrate 110 and define these accommodating spaces S with the pixel structure layer 120. Each first reflective structure 130 is in an annular shape, surrounding the light emitting surface EL of the corresponding micro light emitting device E. In this embodiment, from a cross-sectional view, the shape of the first reflective structure 130 is triangular, and the opening of the accommodating space S gradually decreases from the direction away from the pixel structure layer 120 toward the direction adjacent to the pixel structure layer 120. That is, the shape of the accommodating space S is an inverted trapezoid, but the disclosure is not limited thereto. In another embodiment, the shape of the first reflective structure 130 may also be other polygons, such as a regular trapezoid, but the disclosure is not limited thereto. In addition, the accommodating space S is divided into a first accommodating space S1 and a second accommodating space S2, and the dimensions of each first accommodating space S1 are the same as the dimensions of each second accommodating space S2.

Moreover, in this embodiment, each optical structure 140a is located in the first accommodating space S1, fills the first accommodating space S1 and extends along the Y-axis direction to the outside of the first accommodating space S1, in which the optical structure 140a directly contacts the light emitting surface EL of the micro light emitting device E exposed by the first accommodating space S1, and the first reflective structure 130 directly contacts and covers the peripheral surface 141a of the optical structure 140a. Each optical structure 140a has a top surface 142a away from the circuit substrate 110, where the top surface 142a is exposed outside the first accommodating space S1, and the top surface 142a is, for example, a flat surface.

Referring to FIG. 1 again, each optical structure 140a has a maximum width D1 (such as the width of the top surface 142a in the X-axis direction), and the corresponding light emitting surface EL of each micro light emitting device E has a light emitting width D2, where the maximum width D1 is greater than the light emitting width D2, i.e., D1>D2. On the other hand, preferably, the orthographic projection area of the light emitting surface EL on the circuit substrate 110 is at least greater than 0.5 times the orthographic projection area of the light emitting layer 124 on the circuit substrate 110, which may prevent from blocking the light intensity of the micro light emitting device E. In addition, two adjacent micro light emitting elements 140a have a pitch D in the extending direction parallel to the circuit substrate 110 (i.e., in the X-axis direction), and the maximum width D1 of the optical structure 140a is less than or equal to the pitch D, i.e., D1≤D, which may prevent from blocking light emission.

It should be noted that, continue to refer to FIG. 1, from a cross-sectional view, the aforementioned pitch D may be the connection distance between the center of the micro light emitting device E to the center of the adjacent micro light emitting device E, or may be the connection distance between the edge of the second type semiconductor layer 126 of the micro light emitting device E to the edge of the second type semiconductor layer 126 of the adjacent micro light emitting device E. Because the dimensions of each micro light emitting device E are substantially the same, the distances defined by the above two examples should be the same. In addition, the distance between adjacent first reflective structures 130 should also be the same as the distance between adjacent micro light emitting elements E, thus it may also be described that the "pitch" is also equal to the distance between adjacent first reflective structures 130. For example, the pitch should be equal to the connection distance between the rightmost edge of the bottom edge of the first reflective structure 130 to the rightmost edge of the bottom edge of the adjacent first reflective structure 130.

Furthermore, in this embodiment, the first reflective structure 130 has a first height H1 relative to the light emitting surface EL, where the first height H1 is also the length of the first reflective structure 130 in the Y-axis direction, for example, 2.6 micrometers. The optical structure 140a has a second height H21 relative to the light emitting surface EL, where the second height H21 is also the length of the optical structure 140a in the Y-axis direction, for example, 6.05 micrometers. The ratio of the second height H21 of the optical structure 140a to the first height H1 of the first reflective structure 130 is greater than 1, i.e., H21/H1>1, for example, between 1.4 and 2.5. That is, the second height H21 of the optical structure 140a is higher than the first height H1 of the surrounding first reflective structure 130.

In this embodiment, the optical structure 140a includes, for example, light-filtering material or color conversion material. For example, the optical structure 140a may be colored photoresist material or quantum dot material, to improve the color purity of blue sub pixels in the micro light emitting device apparatus 100a.

In addition, referring again to FIG. 1, in this embodiment, the micro light emitting device apparatus 100a further includes a plurality of color conversion layers 150 and 155, respectively configured in the second accommodating space S2, filling the second accommodating space S2 and directly contacting the light emitting surface EL of the corresponding micro light emitting device E.

Each color conversion layer 150 and 155 has a third height H3 relative to the light emitting surface EL, where the third height H3 is also the length of the color conversion layer 150 and 155 in the Y-axis direction. In this embodiment, the third height H3 of the color conversion layer 150 (or color conversion layer 155) equals the first height H1 of the first reflective structure 130, i.e., H3=H1. That is, the color conversion layer 150 (or color conversion layer 155) is flush with the first reflective structure 130. In addition, the second height H21 of the optical structure 140a is greater than the third height H3 of the color conversion layer 150 (or color conversion layer 155), i.e., H21>H3, meaning that the top surface 142a of the optical structure 140a is exposed above the color conversion layers 150 and 155. In one embodiment, when the micro light emitting device E is a blue light micro light emitting chip, the color conversion layer 150 may be a red light color conversion layer, and the color conversion layer 155 may be a green light color conversion layer. In one embodiment, the color conversion layer 150, the color conversion layer 155, and the optical structure 140a may be arranged alternately in sequence.

In addition, in this embodiment, the micro light emitting device apparatus 100a may further include a first filter layer 160a, configured on these color conversion layers 155 and 155, and surrounding the peripheral surface 141a of each optical structure 140a protruding from the first reflective structure 130, and exposing the top surface 142a of the optical structure 140a. For example, the first filter layer 160a may be a yellow filter layer, allowing red light R and green light G to pass through, to enhance the color purity of red sub pixels and green sub pixels in the micro light emitting device apparatus 100a.

The first filter layer 160a has a fourth height H4 relative to the light emitting surface EL, and the fourth height H4 equals the second height H21 of the optical structure 140a. That is, the first filter layer 160a, besides exposing the top surface 142a of each optical structure 140a, has a height relative to the circuit substrate 110 that is flush with each optical structure 140a, meaning the top surface 142a of the optical structure 140a is flush with the top surface 161a of the first filter layer 160a, to improve the uniformity of subsequent processes.

Since the second height H21 of the optical structure 140a in this embodiment is higher than the first height H1 of the surrounding first reflective structure 130, in addition to defining the position of the first filter layer 160a in subsequent processes through the configuration of the optical structure 140a, it may also prevent the first filter layer 160a from remaining in non-target area sub pixel areas, which may enhance the optical performance of the micro light emitting device apparatus 100a in this embodiment and the uniformity of subsequent processes.

It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

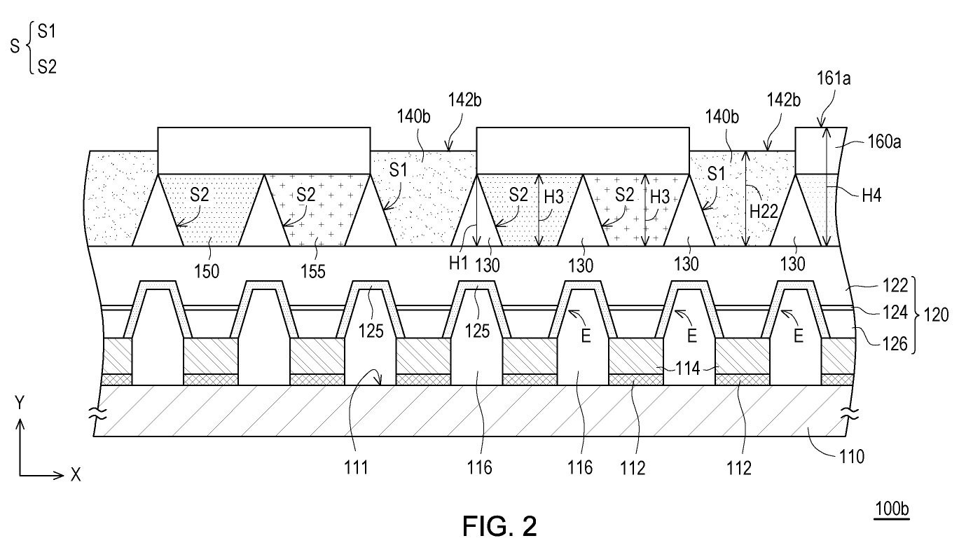

FIG. 2 is a cross-sectional schematic diagram of a micro light emitting device apparatus according to another embodiment of the disclosure. Referring to FIGS. 1 and 2 simultaneously, the micro light emitting device apparatus 100b of this embodiment resembles the above-mentioned micro light emitting device apparatus 100a, with the difference between the two being: in this embodiment, the fourth height H4 of the first filter layer 160a relative to the light emitting surface EL is greater than the second height H22 of the optical structure 140b, that is, H4>H22. In other words, the top surface 142b of the optical structure 140b is lower than the top surface 161a of the first filter layer 160a, with a height difference between them.

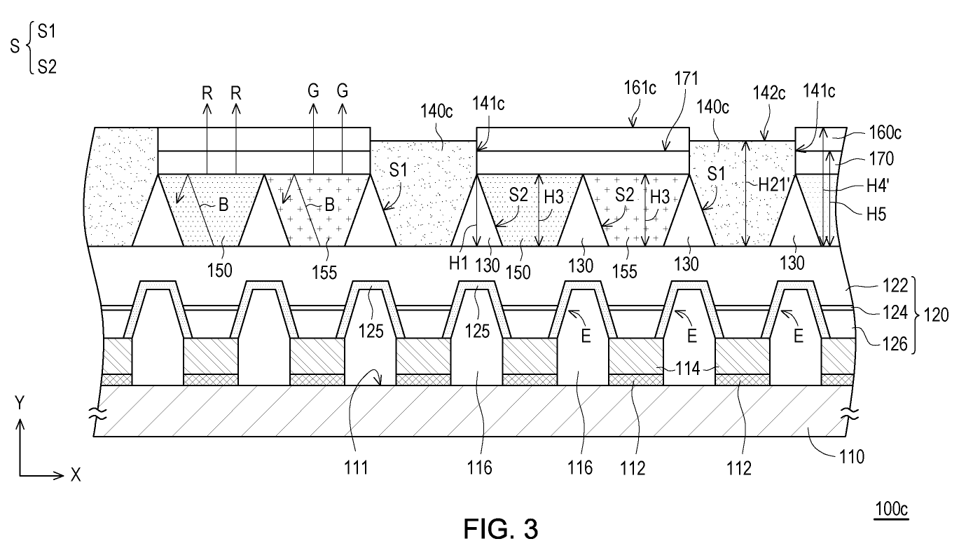

FIG. 3 is a cross-sectional schematic diagram of a micro light emitting device apparatus according to another embodiment of the disclosure. Referring to FIGS. 1 and 3 simultaneously, the micro light emitting device apparatus 100c of this embodiment resembles the above-mentioned micro light emitting device apparatus 100a, with the difference between the two being: in this embodiment, the micro light emitting device apparatus 100c further includes a second filter layer 170, configured on these color conversion layers 150 and 155 and positioned between the first filter layer 160c and these color conversion layers 150 and 155. For example, the second filter layer 170 may be set corresponding to red sub pixels and green sub pixels. Here, the second filter layer 170 surrounds and directly contacts each peripheral surface 141c of the optical structure 140c that protrudes from the first reflective structure 130.

In addition, the second filter layer 170 has a fifth height H5 relative to the light emitting surface EL, where the second height H21' of the optical structure 140c is between the fourth height H4' of the first filter layer 160c and the fifth height H5 of the second filter layer 170. In other words, the top surface 142c of the optical structure 140c is lower than the top surface 161c of the first filter layer 160c, and higher than the top surface 171 of the second filter layer 170. In one embodiment, the lowest position of the top surface 142c of the optical structure 140c may be flush with the top surface 171 of the second filter layer 170, while the highest position of the top surface 142c of the optical structure 140c may be flush with the top surface 161c of the first filter layer 160c.

In this embodiment, when the micro light emitting device E is a blue light micro light emitting chip, the color conversion layer 150 is a red light color conversion layer, and the color conversion layer 155 is a green light color conversion layer, the second filter layer 170 may be, for example, a band pass filter, and set between the first filter layer 160c and these color conversion layers 150 and 155. In addition to reflecting blue light B in the color conversion layers 150 and 155 to enhance the color purity of red sub pixels and green sub pixels, it may also reduce manufacturing process procedures because the second filter layer 170 simultaneously covers the color conversion layers 150 and 155, thereby improving process rate.

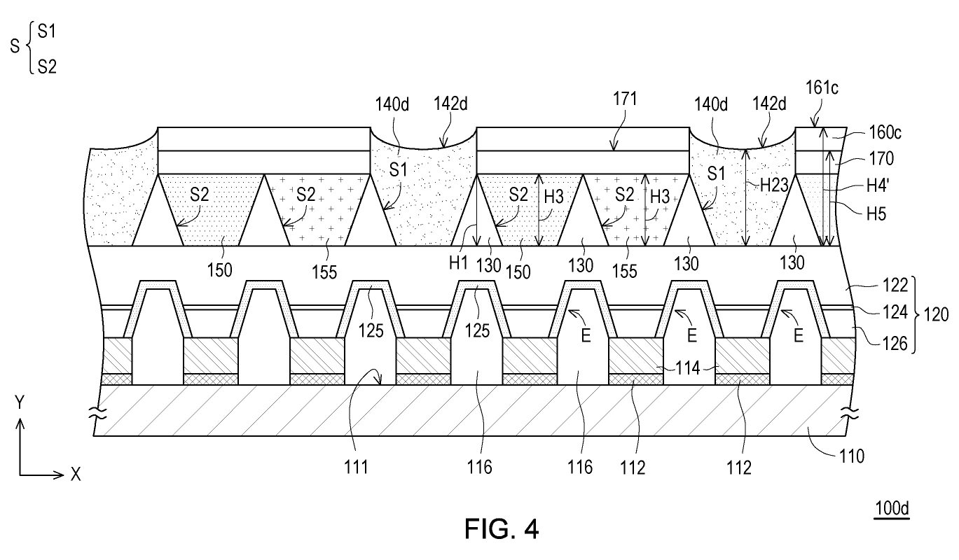

FIG. 4 is a cross-sectional schematic diagram of a micro light emitting device apparatus according to another embodiment of the disclosure. Referring to FIGS. 3 and 4 simultaneously, the micro light emitting device apparatus 100d of this embodiment resembles the above-mentioned micro light emitting device apparatus 100c, with the difference between the two being: in this embodiment, the top surface 142d of each optical structure 140d is a concave surface, meaning that the top surface 142d of the optical structure 140d is lower than the top surface 161c of the first filter layer 160c, and the top surface 142d of the optical structure 140d is concave from the top surface 161c of the first filter layer 160c toward the direction of the adjacent circuit substrate 110. That is, the second height H23 of the optical structure 140d is between the fourth height H4' of the first filter layer 160c and the fifth height H5 of the second filter layer 170.

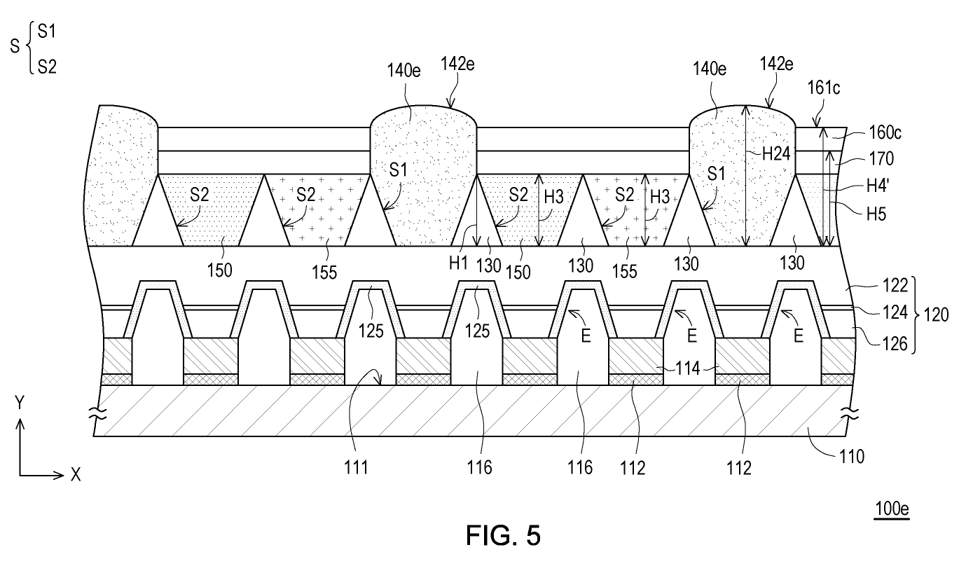

FIG. 5 is a cross-sectional schematic diagram of a micro light emitting device apparatus according to another embodiment of the disclosure. Referring to FIGS. 3 and 5 simultaneously, the micro light emitting device apparatus 100e of this embodiment resembles the above-mentioned micro light emitting device apparatus 100c, with the difference between the two being: in this embodiment, the top surface 142e of each optical structure 140e is a convex surface, meaning that the top surface 142e of the optical structure 140e is higher than the top surface 161c of the first filter layer 160c, and the top surface 142e of the optical structure 140e protrudes from the top surface 161c of the first filter layer 160c toward the direction away from the circuit substrate 110, which may make the light in the corresponding sub pixel area (such as blue sub pixel) more concentrated.

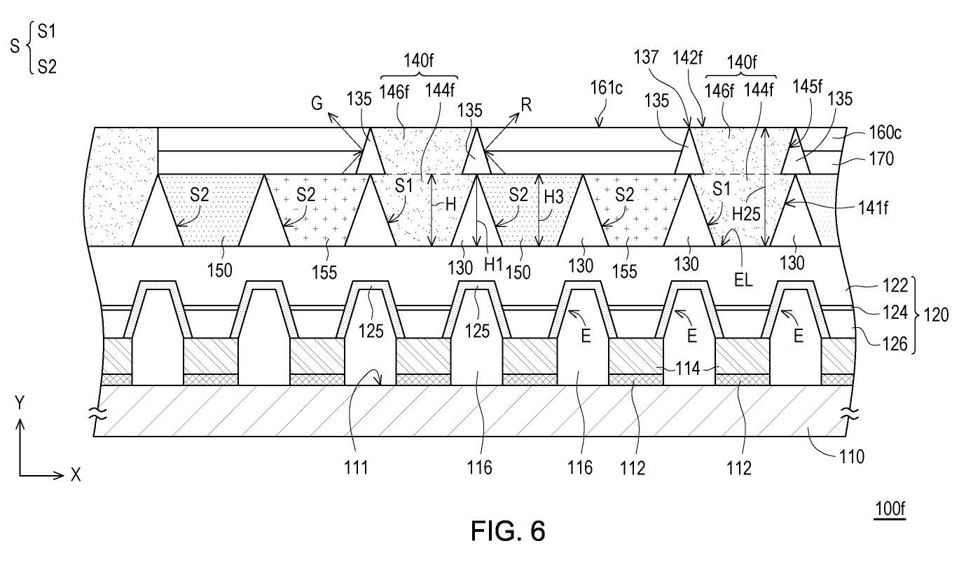

FIG. 6 is a cross-sectional schematic diagram of a micro light emitting device apparatus according to another embodiment of the disclosure. Referring to FIGS. 3 and 6 simultaneously, the micro light emitting device apparatus 100f of this embodiment resembles the above-mentioned micro light emitting device apparatus 100c, with the difference between the two being: in this embodiment, each optical structure 140f includes a stacked first optical portion 144f and a second optical portion 146f. Specifically, the first optical portion 144f is located in the corresponding first accommodating space S1, and its height relative to the light emitting surface EL is flush with the height of the first reflective structure 130 relative to the light emitting surface EL. In addition, each second optical portion 146f is configured on a side of the corresponding first optical portion 144f that is away from the pixel structure layer 120, meaning that the second optical portion 146f is set on the first optical portion 144f in the positive Y-axis direction.

Moreover, the micro light emitting device apparatus 100f of this embodiment further includes a plurality of second reflective structures 135, configured on the first optical portion 144f. Here, both the first reflective structure 130 and the second reflective structure 135 are in annular form, where the first reflective structure 130 covers and surrounds the peripheral surface 141f of the first optical portion 144f, while the second reflective structure 135 covers and surrounds the peripheral surface 145f of the second optical portion 146f. Both the first reflective structure 130 and the second reflective structure 135 are exposed from the light emitting surface EL of the micro light emitting device E, meaning they are set to not block the light emitting path of the light emitting surface EL, thereby may prevent from reducing the light emitting efficiency of each micro light emitting device E. In addition, the setting of the second reflective structure 135 may effectively reflect the side light emitted from adjacent sub pixels. Specifically, the setting of the second reflective structure 135 may prevent side light from adjacent red sub pixels or green sub pixels from entering the second optical portion 146f, which would otherwise cause the emitted light to be absorbed by the photoresist material and, in turn reduce the light intensity. Furthermore, the setting of the second reflective structure 135 may also prevent red light R or green light G from entering the blue sub pixel area, causing crosstalk problems between sub pixels.

In addition, the orthographic projection area of the first reflective structure 130 on the circuit substrate 110 is larger than and covers the corresponding orthographic projection area of the second reflective structure 135 on the circuit substrate 110. In other words, the orthographic projection area of the second reflective structure 135 on the circuit substrate 110 completely falls within the orthographic projection area of the first reflective structure 130 on the circuit substrate 110. From a cross-sectional view, along the X-axis, the width of the first reflective structure 130 is greater than the width of the second reflective structure 135. That is, the first reflective structure 130 and the second reflective structure 135 present a contracted state along the Y-axis, meaning larger at the bottom and smaller at the top. In this embodiment, from a cross-sectional view, along the Y-axis, both the first reflective structure 130 and the second reflective structure 135 present a triangular shape, with their center lines aligned with each other, but this is not limited thereto. Furthermore, the material of the first reflective structure 130 may be the same as the material of the second reflective structure 135, for example, a metal reflective layer. For example, the material of the first reflective structure 130 and the material of the second reflective structure 135 may be aluminum, which may effectively reflect side light from adjacent sub pixels to increase the frontal light emission of red sub pixels or green sub pixels, but this is not limited thereto.

In addition, the first optical portion 144f has a height H relative to the light emitting surface EL, and the height H is equal to the first height H1 of the first reflective structure 130 and equal to the third height H3 of the color conversion layer 150 (or color conversion layer 155), that is, H=H1=H3. In other words, the height H of the first optical portion 144f relative to the light emitting surface EL is flush with the first height H1 of the first reflective structure 130 relative to the light emitting surface EL and the third height H3 of the color conversion layer 150 and 155 relative to the light emitting surface EL. Moreover, the second optical portion 146f has a top surface 142f, and the second reflective structure 135 has a top portion 137, while the top surface 142f is flush with the top surface 161c of the first filter layer 160c and the top portion 137 of the second reflective structure 135, which helps the uniformity of subsequent coating processes.

The ratio of the second height H25 of the optical structure 140f relative to the light emitting surface EL to the first height H1 of the first reflective structure 130 relative to the light emitting surface EL is greater than 1, that is, H25/H1>1. In one embodiment, the ratio of the second height H25 of the optical structure 140f to the first height H1 of the first reflective structure 130 may be between 1.4 and 2.5.

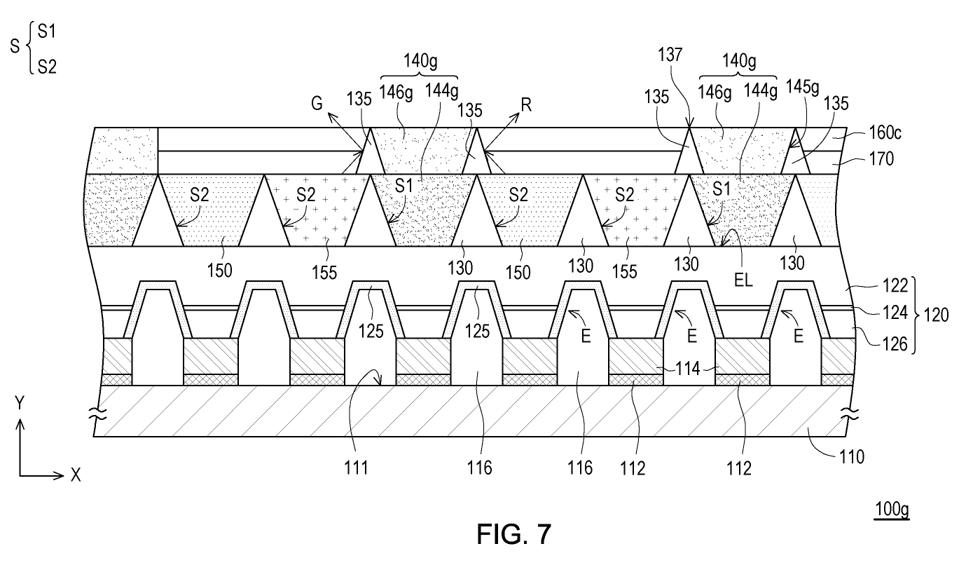

FIG. 7 is a cross-sectional schematic diagram of a micro light emitting device apparatus according to another embodiment of the disclosure. Referring to FIGS. 6 and 7 simultaneously, the micro light emitting device apparatus 100g of this embodiment resembles the aforementioned micro light emitting device apparatus 100f, with the difference between the two being: in this embodiment, each optical structure 140g includes a stacked first optical portion 144g and a second optical portion 146g, where the material of the first optical portion 144g is different from the material of the second optical portion 146g. For example, the material of the first optical portion 144g may be blue photoresist material, which may selectively limit blue light of specific wavelength ranges to pass through, and filter other wavelength light from entering the blue sub pixel area, thereby improving the blue light color purity and saturation of the micro light emitting device apparatus 100g. In addition, the material of the second optical portion 146g may be transparent photoresist material, which may reduce the impact of light leakage to adjacent sub pixels (such as affecting the light emitting efficiency of red light or green light). Specifically, in this embodiment, the configuration of the second reflective structure 135 results in a smaller opening for the second optical portion 146g, which is prone to leakage into adjacent sub pixel areas during the process and may affect optical efficiency. Thus, the different materials of the first optical portion 144g and the second optical portion 146g may enhance the design flexibility of the micro light emitting device apparatus 100g and improve the overall optical performance.

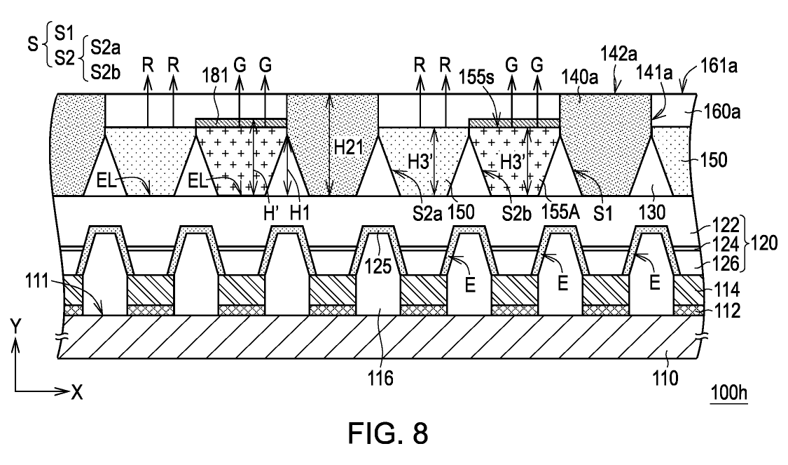

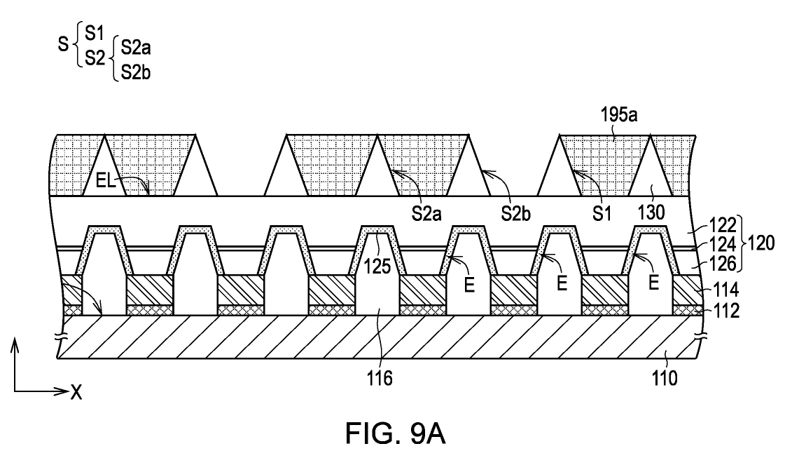

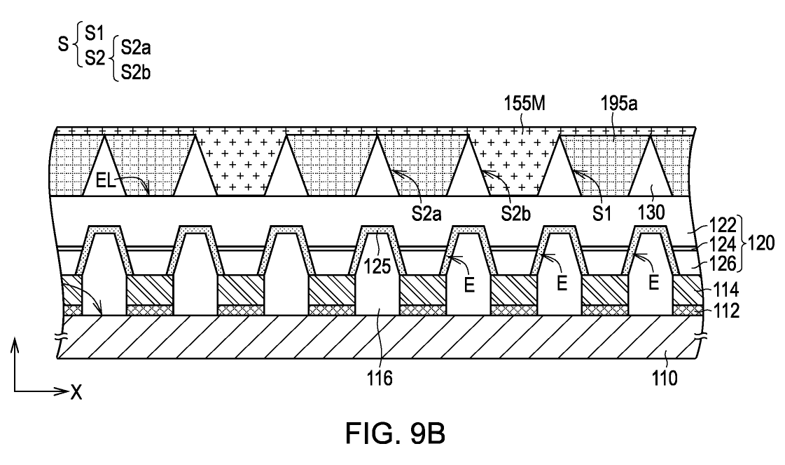

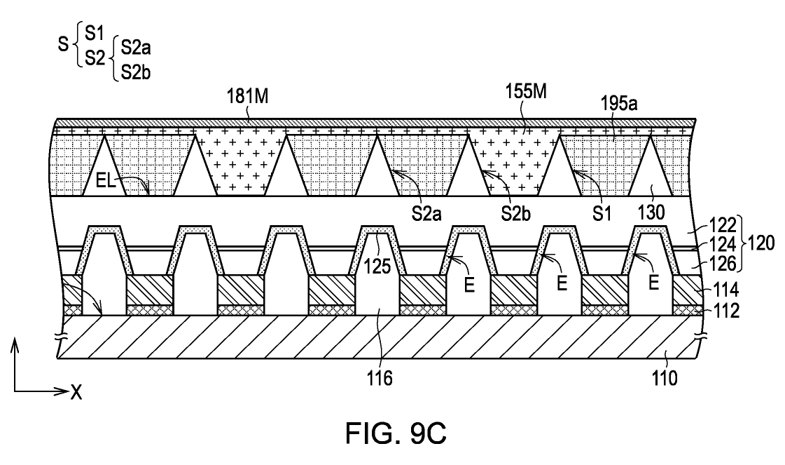

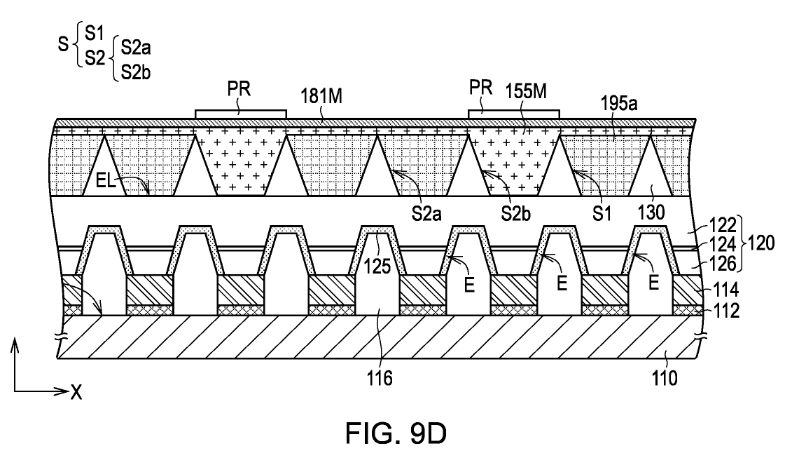

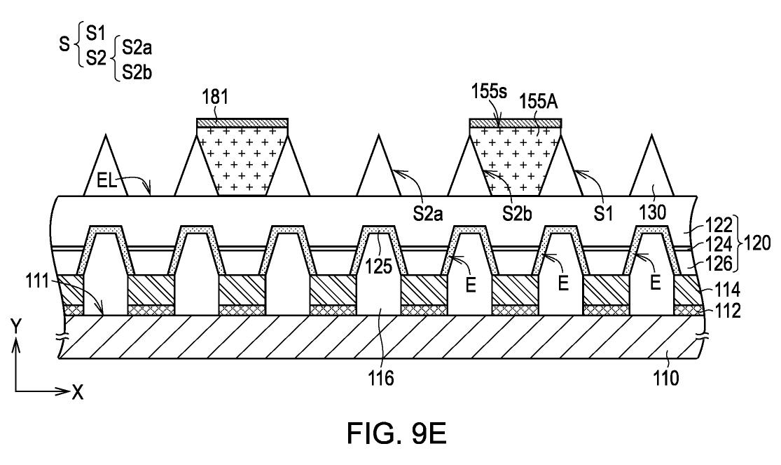

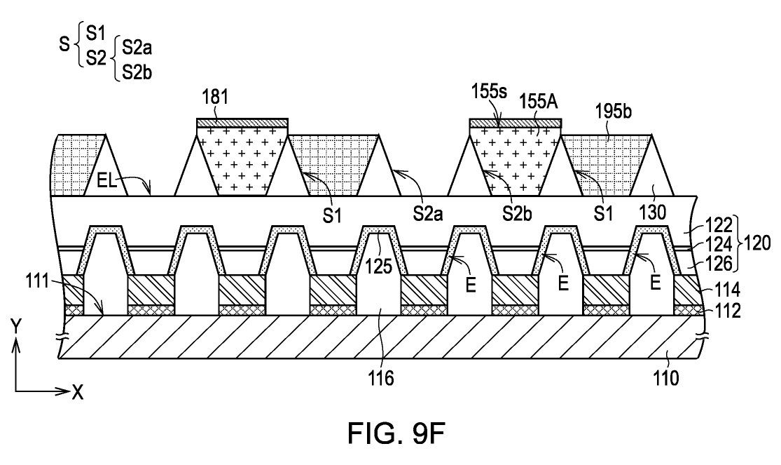

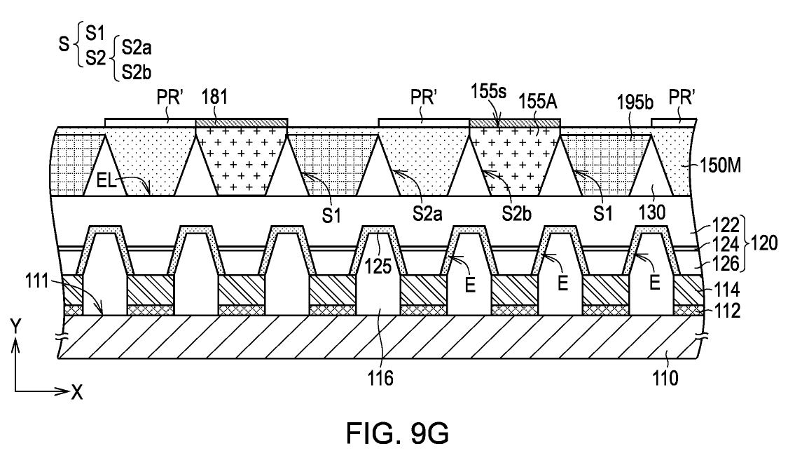

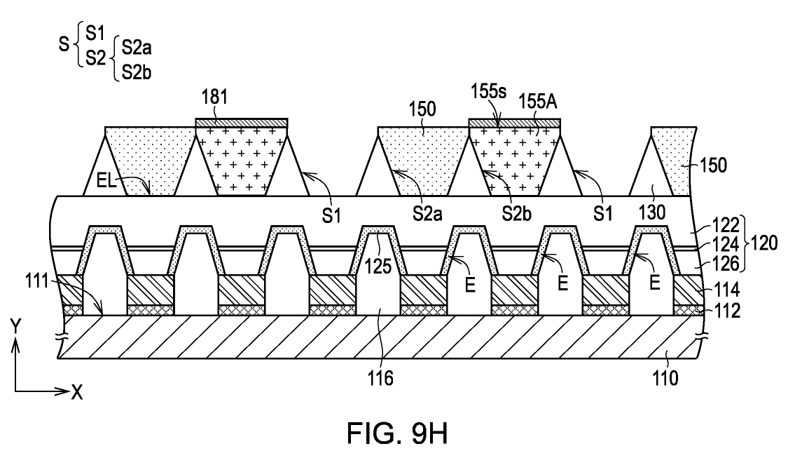

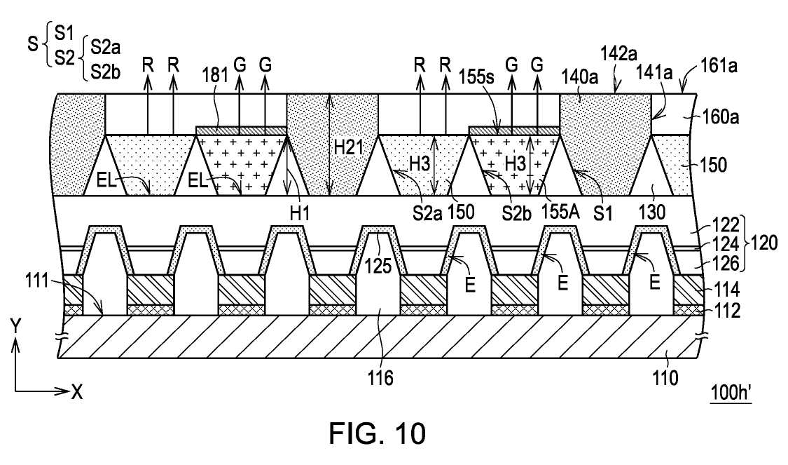

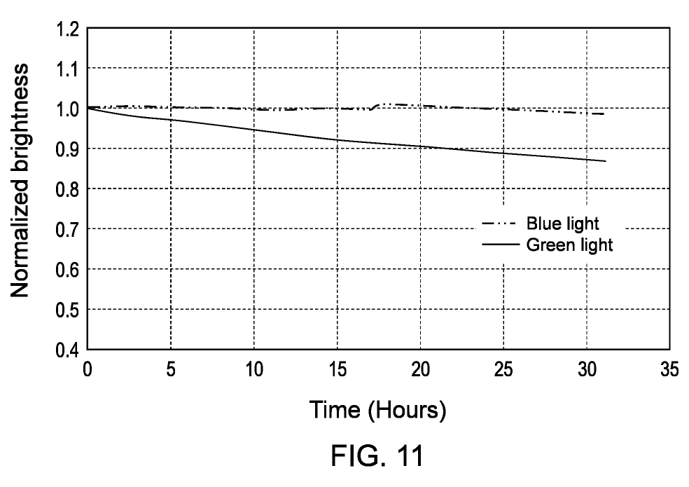

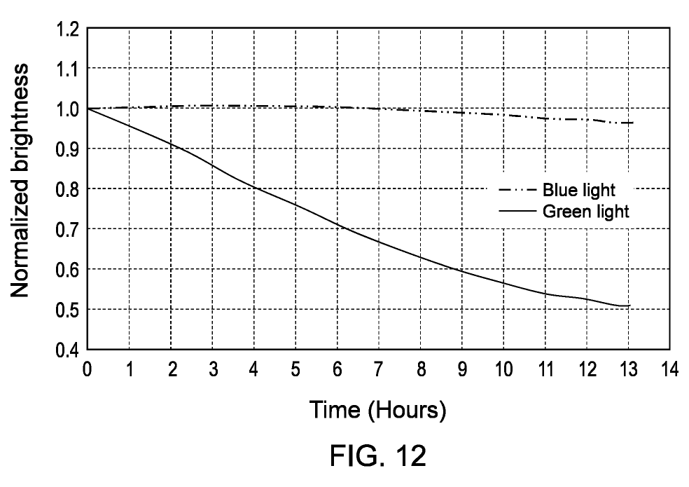

FIG. 8 is a cross-sectional schematic diagram of a micro light emitting device apparatus according to another embodiment of the disclosure. FIGS. 9A-9H are cross-sectional schematic diagrams illustrating a manufacturing process of the micro light emitting device apparatus of FIG. 8. FIG. 10 is a cross-sectional schematic diagram of a micro light emitting device apparatus according to another embodiment of the disclosure. FIG. 11 is a graph illustrating normalized brightness of blue light and green light emitted from the micro light emitting device apparatus of FIG. 8 as a function of time. FIG. 12 is a graph illustrating normalized brightness of blue light and green light emitted from a micro light emitting device apparatus of a comparative example as a function of time.

Referring to FIG. 8, compared with the micro light emitting device apparatus 100a of FIG. 1, a micro light emitting device apparatus 100h of this embodiment may further include a plurality of first protective layers 181 disposed between the plurality of color conversion layers 155A and the first filter layer 160a. Each of the plurality of first protective layers 181 directly contacts a surface 155s of a corresponding one of the plurality of color conversion layers 155A.

It should be noted that, in this embodiment, the plurality of color conversion layers 155A are fabricated prior to fabrication of the plurality of color conversion layers 150. The provision of the first protective layers 181 can prevent the color conversion layers 155A from generating defects or degradation due to contact with or intrusion of process materials (for example, etching gases) during subsequent processes (for example, processes for forming the color conversion layers 150), thereby avoiding structural damage or a decrease in light-emitting efficiency.

For example, in this embodiment, the color conversion layers 150 may be formed of a photoresist material doped with quantum dots, and the color conversion layers 155A may be formed of a printing ink doped with quantum dots. Since the color conversion layers 150 of the embodiment have better process tolerance than the color conversion layers 155A during fabrication, no protective layer is required on the color conversion layers 150, but the disclosure is not limited thereto.

In this embodiment, each micro light emitting device E may be a blue light micro light emitting chip, the color conversion layers 150 may be red light color conversion layers, and the color conversion layers 155A may be green light color conversion layers. In a comparative example, if the color conversion layers 155A are not covered with the first protective layers 181, after a high-temperature test (e.g., at a temperature between 85°C and 90°C) for 2.5 hours, the brightness of green light emitted from the fabricated micro light emitting device apparatus decreases to below 90% of an initial brightness (as shown in FIG. 12). During the high-temperature test, the brightness stability of the green light is significantly lower than that of the blue light.

In this embodiment, each of the color conversion layers 155A is covered with the first protective layers 181. Accordingly, after a high-temperature test for 20 hours, the brightness of green light emitted from the micro light emitting device apparatus 100h of this embodiment can still be maintained at greater than 90% of an initial brightness (as shown in FIG. 11). That is, the provision of the first protective layers 181 can indeed ensure that a structure and characteristics of the color conversion layers 155A are not affected by process materials during subsequent processes.

The following provides an exemplary description of a portion of a manufacturing process of the micro light emitting device apparatus 100h.

Referring to FIG. 9A, after forming the plurality of first reflective structures 130, a first sacrificial layer 195a is formed in a portion of the plurality of second accommodating spaces S2 (e.g., a plurality of second accommodating spaces S2a) and in the plurality of first accommodating spaces S1. Next, a color conversion material layer 155M is coated such that a remaining portion of the plurality of second accommodating spaces S2 (e.g., a plurality of second accommodating spaces S2b) is filled with the color conversion material layer 155M, as shown in FIG. 9B. In this embodiment, a material of the color conversion material layer 155M includes, for example, an epoxy-acrylic ink, but the disclosure is not limited thereto.

After completing coating of the color conversion material layer 155M, a protective material layer 181M is formed on the color conversion material layer 155M, as shown in FIG. 9C. In this embodiment, a material of the protective material layer 181M is, for example, an inorganic material, and the inorganic material may include silicon dioxide (SiO₂) or aluminum nitride (AlN). Methods for forming the protective material layer 181M includes, for example, chemical vapor deposition (CVD), physical vapor deposition (PVD), or atomic layer deposition (ALD), but the disclosure is not limited thereto.

Referring to FIGS. 9D and 9E, next, a patterning process is performed on the color conversion material layer 155M to form the plurality of color conversion layers 155A and the plurality of first protective layers 181. The aforementioned patterning process is, for example, a photolithography and etching process. Steps thereof may include forming a photoresist pattern PR above each of the second accommodating spaces S2b filled with the color conversion material layer 155M, and performing an etching step on the protective material layer 181M, the color conversion material layer 155M, and the first sacrificial layer 195a by using the photoresist pattern PR as a hard mask, but the disclosure is not limited thereto.

After forming the plurality of color conversion layers 155A, a second sacrificial layer 195b is formed in the plurality of first accommodating spaces S1, as shown in FIG. 9F. Next, a color conversion material layer 150M is coated such that the plurality of second accommodating spaces S2a are filled with the color conversion material layer 150M, as shown in FIG. 9G. In this embodiment, a material of the color conversion material layer 150M includes, for example, a photoresist material, but the disclosure is not limited thereto.

Referring to FIGS. 9G and 9H, next, a patterning process is performed on the color conversion material layer 150M to form the plurality of color conversion layers 150. The aforementioned patterning process is, for example, a photolithography and etching process. Steps thereof may include forming a photoresist pattern PR’ above each of the second accommodating spaces S2a filled with the color conversion material layer 150M, and performing an etching step on the color conversion material layer 155M and the second sacrificial layer 195b by using the photoresist pattern PR’ as a hard mask, but the disclosure is not limited thereto.

Referring to FIGS. 8 and 9H, after completing the plurality of color conversion layers 150, a plurality of optical structures 140a are formed in the plurality of first accommodating spaces S1. Next, a first filter layer 160a is formed on the plurality of color conversion layers 150 and the plurality of color conversion layers 155A. The first filter layer 160a surrounds the peripheral surface 141a of each of the plurality of optical structures 140a. At this point, fabrication of the micro light emitting device apparatus 100h of this embodiment is completed.

In this embodiment, the third height H3’ of each of the plurality of color conversion patterns 150 and the plurality of color conversion patterns 155A is greater than the first height H1 of the first reflective structures 130. Accordingly, each of the first protective layers 181 has a height H’ relative to the light emitting surface EL, and the height H’ is greater than the first height H1 of the first reflective structures 130.

However, the disclosure is not limited thereto. Referring to FIG. 10, in a micro light emitting device apparatus 100h’ of another embodiment, the third height H3 of each of the plurality of color conversion patterns 150 and the plurality of color conversion patterns 155A is equal to the first height H1 of the first reflective structures 130. Accordingly, each of the first protective layers 181 is in close contact with two adjacent ones of the plurality of first reflective structures 130 and one of the plurality of color conversion layers 155A. That is, each of the color conversion layers 155A may be completely enclosed by two adjacent first reflective structures 130 and the first protective layer 181, such that process materials in subsequent processes are prevented from contacting the color conversion layers 155A, thereby helping to further reduce a risk of defects or degradation of the color conversion layers 155A during subsequent processes.

In a modified embodiment not shown, the first filter layer 160a in FIGS. 8 or 10 may extend from above the plurality of color conversion layers 150 and the plurality of color conversion layers 155A into the plurality of first accommodating spaces S1 to replace the plurality of optical structures 140a.

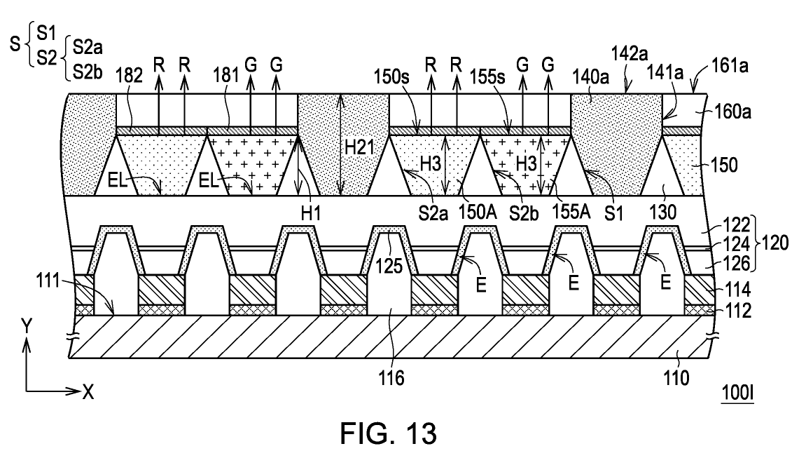

FIG. 13 is a cross-sectional schematic diagram of a micro light emitting device apparatus according to another embodiment of the disclosure.

Referring to FIG. 13, in this embodiment, the micro light emitting device apparatus 100I may further include a plurality of second protective layers 182 disposed between the plurality of color conversion layers 150A and the first filter layer 160a. Each of the plurality of second protective layers 182 directly contacts a surface 150s of a corresponding one of the plurality of color conversion layers 150A. Similar to a function of the first protective layers 181, the provision of the second protective layers 182 can prevent the color conversion layers 150A from generating defects or degradation due to contact with or intrusion of process materials (for example, etching gases) during subsequent processes (for example, processes for forming the plurality of optical structures 140a), thereby avoiding structural damage or a decrease in light-emitting efficiency. In this embodiment, the color conversion layers 155A for emitting green light and the color conversion layers 150A for emitting red light may both be formed of printing ink doped with quantum dots.

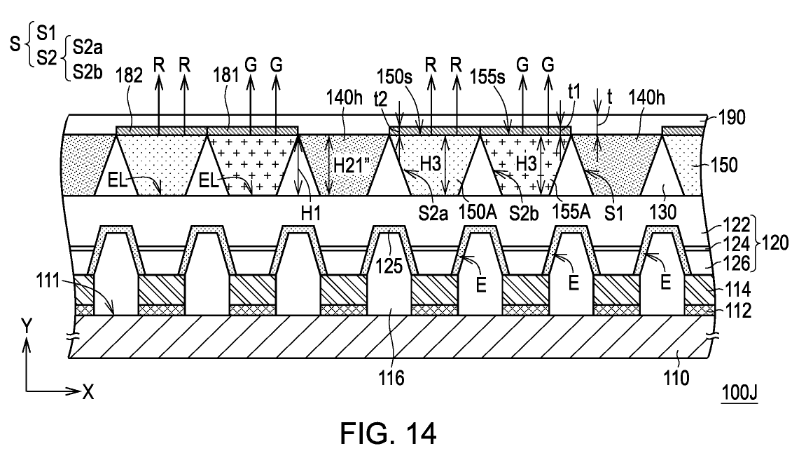

FIG. 14 is a cross-sectional schematic diagram of a micro light emitting device apparatus according to another embodiment of the disclosure.

Referring to FIG. 14, unlike the micro light emitting device apparatus 100I of FIG. 13, in a micro light emitting device apparatus 100J of this embodiment, the height H21” of each optical structure 140h relative to the light emitting surface EL may be equal to the first height H1 of each first reflective structure 130, and the micro light emitting device apparatus 100J does not include the first filter layer 160a of FIG. 13.

In this embodiment, the micro light emitting device apparatus 100J may further include a planarization layer 190 covering the plurality of color conversion layers 150A, the plurality of color conversion layers 155A, and the plurality of optical structures 140h. It should be noted that a thickness t of the planarization layer 190 is greater than a thickness t1 of the first protective layers 181 and a thickness t2 of the second protective layers 182. For example, the thickness t of the planarization layer 190 may range from 1.2 μm to 1.25 μm, but the disclosure is not limited thereto. Preferably, a ratio of the thickness t of the planarization layer 190 to the thickness t1 of the first protective layers 181 or the thickness t2 of the second protective layers 182 may range from 1.5 to 2.

It should be particularly noted that the planarization layer 190 of this embodiment may also be applied to the embodiments of FIGS. 8 and 10, and thus details thereof are not repeated herein.

In summary, in the design of the micro light emitting device apparatus of the disclosure, a protective layer is disposed on the optical structure and the color conversion layer, and the protective layer is in direct contact with a surface of the color conversion layer. Accordingly, defects or degradation of the color conversion layer caused by contact with process materials in subsequent processes can be avoided, thereby preventing structural damage or reduced light-emitting efficiency. The provision of the protective layer not only improves the manufacturing yield of the micro light emitting device apparatus, but also significantly enhances its tolerance in high-temperature testing environments.

Although the disclosure has been described in detail with reference to the above embodiments, they are not intended to limit the disclosure. Those skilled in the art should understand that it is possible to make changes and modifications without departing from the spirit and scope of the disclosure. Thus, the protection scope of the disclosure shall be defined by the following claims.

What is claimed is:

1. A micro light emitting device apparatus, comprising:
a circuit substrate;
a pixel structure layer, configured on the circuit substrate and comprising a plurality of micro light emitting elements;
a plurality of first reflective structures, configured on a side of the pixel structure layer away from the circuit substrate and defining a plurality of accommodating spaces with the pixel structure layer, each of the plurality of accommodating spaces exposing a light emitting surface of one of the plurality of micro light emitting elements, and the plurality of accommodating spaces comprising a plurality of first accommodating spaces and a plurality of second accommodating spaces;
a plurality of optical structures, respectively configured in the plurality of first accommodating spaces;
a plurality of first color conversion layers, configured in a part of the plurality of second accommodating spaces; and
a plurality of first protective layers, respectively configured on the plurality of first color conversion layers, wherein each of the plurality of first protective layers directly contacts a surface of one of the plurality of first color conversion layers.

2. The micro light emitting device apparatus according to claim 1, wherein each of the plurality of first reflective structures has a first height relative to the light emitting surface, each of the plurality of optical structures has a second height relative to the light emitting surface, and the second height is greater than or equal to the first height.

3. The micro light emitting device apparatus according to claim 2, further comprising:
a planarization layer, covering the plurality of first protective layers.

4. The micro light emitting device apparatus according to claim 3, wherein a thickness of the planarization layer is greater than a thickness of each of the plurality of first protective layers.

5. The micro light emitting device apparatus according to claim 2, wherein each of the plurality of first protective layers has a height relative to the light emitting surface, and the height is greater than the first height.

6. The micro light emitting device apparatus according to claim 1, wherein the plurality of first protective layers are made of an inorganic material.

7. The micro light emitting device apparatus according to claim 1, wherein the plurality of first color conversion layers are made of a printing ink.

8. The micro light emitting device apparatus according to claim 7, wherein the plurality of first color conversion layers are green light color conversion layers.

9. The micro light emitting device apparatus according to claim 7, wherein each of the plurality of first reflective structures has a first height relative to the light emitting surface, each of the plurality of first color conversion layers has a third height relative to the light emitting surface, and the first height is equal to the third height.

10. The micro light emitting device apparatus according to claim 7, wherein each of the plurality of first protective layers is in close contact with two adjacent ones of the plurality of first reflective structures and one of the plurality of first color conversion layers.

11. The micro light emitting device apparatus according to claim 7, wherein each of the plurality of first reflective structures has a first height relative to the light emitting surface, each of the plurality of first color conversion layers has a third height relative to the light emitting surface, and the third height is greater than the first height.

12. The micro light emitting device apparatus according to claim 1, further comprising:
a plurality of second color conversion layers, configured in another part of the plurality of second accommodating spaces.

13. The micro light emitting device apparatus according to claim 12, wherein the plurality of second color conversion layers are made of a photoresist material.

14. The micro light emitting device apparatus according to claim 12, further comprising:
a first filter layer, configured on the plurality of first color conversion layers and the plurality of second color conversion layers, and surrounding a peripheral surface of each of the plurality of optical structures.

15. The micro light emitting device apparatus according to claim 14, wherein the plurality of first protective layers are disposed between the first filter layer and the plurality of first color conversion layers.

16. The micro light emitting device apparatus according to claim 12, wherein the plurality of second color conversion layers are made of a printing ink.

17. The micro light emitting device apparatus according to claim 16, further comprising:
a plurality of second protective layers, respectively configured on the plurality of second color conversion layer, wherein each of the plurality of second protective layer directly contacts a surface of one of the plurality of second color conversion layers.

18. The micro light emitting device apparatus according to claim 17, wherein the plurality of second protective layers are made of an inorganic material.

19. The micro light emitting device apparatus according to claim 17, further comprising:
a planarization layer, covering the plurality of first protective layers and the plurality of second protective layers.

20. The micro light emitting device apparatus according to claim 19, wherein a thickness of the planarization layer is greater than a thickness of each of the plurality of first protective layers and the plurality of second protective layers.
